(19) United States
(12) Patent Application Publication
(10) Pub. No.: US 2024/0200192 A1
(43) Pub. Date: Jun. 20, 2024

(54) STAGE FOR HEATING AND COOLING OBJECT

(71) Applicant: ADVANTEC CO., LTD., Tokyo (JP)

(72) Inventor: Yuji Masuda, Tokyo (JP)

(73) Assignee: ADVANTEC CO., LTD., Tokyo (JP)

(21) Appl. No.: 18/276,620

(22) PCT Filed: Feb. 3, 2022
(86) PCT No.: PCT/JP2022/004189

§ 371 Date: Aug. 9, 2023

(30) Foreign Application Priority Data
Feb. 9, 2021 (JP) 2021-019397

(51) Int. Cl. C23C 16/46; C23C 16/458

(52) U.S. Cl. CPC C23C 16/466; C23C 16/4586

(57) ABSTRACT

A stage 1 that is installed in a chamber and that is for heating and cooling an object, the stage includes: a stage body 5 having a mount surface on which the object is to be mounted; a first pipe-shaped part 7 for causing a first fluid for adjusting the temperature of the mount surface to flow therein; and a first pipe-supporting part 9 for supporting the first pipe-shaped part 7. The stage body 5 has a first groove part 11 for housing the first pipe-shaped part 7, and a pair of cutouts 13a and 13b that oppose each other with the first groove part 11 therebetween. The first pipe-supporting part 9 has a linking section 15 that links the pair of cutouts 13a and 13b together.

### TECHNICAL FIELD

The present invention relates to a stage for heating and cooling an object.

### BACKGROUND ART

Japanese Patent No. 5427367 discloses a rectangular susceptor. Susceptors are used, for example, as stages in the manufacturing of semiconductor integrated circuits, flat display panels, and solar photovoltaic power generation panels. Susceptors heat substrates, for example, in manufacturing processes. At that time, it is required to heat the substrates rapidly and uniformly. It is also desirable that the substrates can be cooled. Therefore, it is conceivable to use a cooling tube and a heating tube for stage temperature control. In this case, when the tubes are simply in contact with the stage, there is a problem that the tubes may come out and the efficiency of temperature control will be lowered. On the other hand, in the case of inserting the tubes into the stage, there is a problem that the processing is difficult and no modification is feasible.

### CITATION LIST

### Patent Literature

Patent Literature 1: Japanese Patent No. 5427367

### SUMMARY OF INVENTION

### Technical Problem

The present invention intends to provide a stage with a tube provided therein, in which the tube can be permanently in contact with the stage by a simple method and modifications can be facilitated.

### Solution to Problem

The above-described problems can be solved by a stage that includes not only a heating part for heating a mount surface of the stage but also a cooling part. Further, the above-described problems can be solved by filling a clearance of a groove that accommodates the heating part or the cooling part with a heat conductive medium.

A first invention relates to a stage 1 installed in a chamber for heating and cooling an object. The stage 1 includes: a stage body 5 with a mount surface for mounting the object; a first tubular part 7 that causes a first fluid to flow for temperature adjustment of the mount surface; and a first tube support part 9 for supporting the first tubular part 7.

Further, the stage body 5 includes: a first groove part 11 for accommodating the first tubular part 7; and paired notches 13a and 13b facing each other across the first groove part 11.

Further, the first tube support part 9 includes a connection part 15 for connecting the paired notches 13a and 13b.

In a preferable example of this stage, a heat conductive medium exists in a clearance between the first tubular part 7 and the first groove part 11. A preferable example of the heat conductive medium is silver, grease, metal fiber, or gas.

As a preferable example of this stage, in the stage according to the first aspect of the invention, the first fluid is a fluid for raising a temperature of the mount surface. The stage further includes: a second tubular part 21 that causes a second fluid to flow for lowering a temperature of the mount surface; a second groove part 23 for accommodating the second tubular part 21; and a second tube support part 25 for supporting the second tubular part 23.

A second invention relates to a vacuum device that includes the above-described stage as a susceptor.

This vacuum device is used, for example, for manufacturing a semiconductor integrated circuit, a flat display panel, or a solar cell panel.

A third invention relates to a method for manufacturing a semiconductor integrated circuit, a flat display panel, or a solar cell panel using the above-described vacuum device.

### Advantageous Effects of Invention

The present invention can provide a stage including a groove part for accommodating a tubular part, paired notches facing each other across the groove part, and a tube support part including a connection part for connecting the paired notches. Therefore, a tube provided in the stage can be permanently in contact with the stage by a simple method, and modifications can be facilitated.

### BRIEF DESCRIPTION OF DRAWINGS

FIG. 1 is a conceptual diagram illustrating how a stage is installed.

FIG. 2 is a schematic diagram illustrating the stage.

FIG. 3 is a partial cross-sectional diagram illustrating the stage.

FIG. 4 is a conceptual diagram illustrating a connection part.

FIG. 5 is a reference diagram illustrating the stage during manufacturing.

FIG. 6 is a conceptual diagram illustrating an exemplary use of a heat conductive medium.

FIG. 7 is a photograph in lieu of a drawing showing a back surface of a stage on which grooves and notched parts are formed.

FIG. 8 is a photograph in lieu of a drawing showing how a tube support part is welded.

### DETAILED DESCRIPTION OF THE INVENTION

Hereinafter, embodiments for carrying out the present invention will be described with reference to attached drawings. The present invention is not limited to the embodiments described below and encompasses appropriate modifications within the scope obvious to those skilled in the art from the following embodiments.

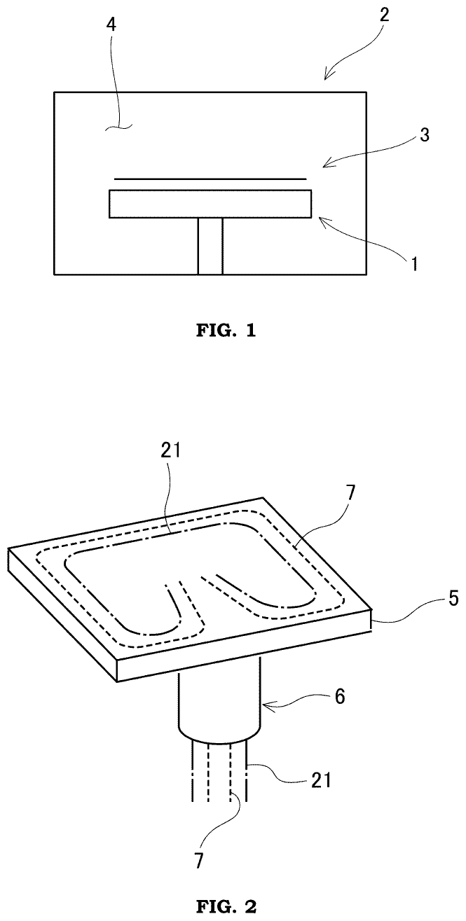

FIG. 1 is a conceptual diagram illustrating how a stage is installed. A stage 1 is usually installed inside a process chamber 2 to perform temperature management for a substrate 3. The process chamber 2 is isolated from the outside air and kept at a desired degree of vacuum. The process chamber 2 may be filled with a process gas 4 and kept under pressure. The pressure of the process gas 4 varies depending on the difference in type of the process chamber. There are different types of process chambers, such as physical vapor deposition (PVD) chambers, sputtering chambers, ion metal implantation (IMP) chambers, chemical vapor deposition (CVD) chambers, atomic layer deposition (ALD) chambers, plasma etching chambers, and annealing chambers.

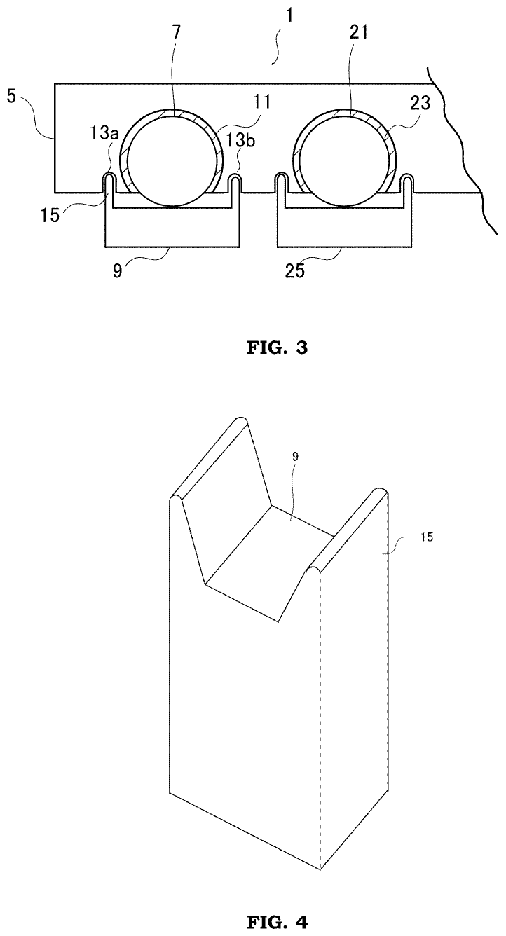

FIG. 2 is a schematic diagram illustrating the stage. FIG. 3 is a partial cross-sectional diagram illustrating the stage. The stage is a mount stand installed in the chamber for heating and cooling an object. A vacuum chamber is an exemplary chamber. Semiconductor integrated circuits, flat display panels, and solar photovoltaic power generation panels, or substrates in the process of manufacturing them are exemplary objects.

As illustrated in FIGS. 1 to 3, the stage 1 includes a stage body 5, a first tubular part 7, and a first tube support part 9. The stage body 5 includes a first groove part 11 and paired notches 13a and 13b. Further, the first tube support part 9 includes a connection part 15. A preferable example of the stage 1 further includes a second tubular part 21, a second groove part 23, and a second tube support part 25. According to the example illustrated in FIGS. 1 to 3, the tubular part is in communication, via the interior of a table support 6, with the outside of the chamber 2. Therefore, the fluid can flow into the tubular part from the outside.

### Stage Body 5

The stage body 5 is a portion including a mount surface for mounting an object.

### First Tubular Part 7

The first tubular part 7 is a tube that causes a first fluid to flow for temperature adjustment of the mount surface. It is preferable that the tubular part includes a material that does not melt when the stage 1 is heated. Appropriately causing a liquid for temperature adjustment to flow in this tube can adjust the temperature of the stage 1. The first tubular part 7 may be a portion configured by a cylindrical tube through which a liquid for cooling the stage 1 flows, for example. The tubular shape of the first tubular part 7 may be, for example, a tubular shape with a bottom surface being a circle having a radius of 5 mm. The radius in the above case may be not less than 3 mm and not greater than 9 mm or may be not less than 4 mm and not greater than 8 mm. The tube may be appropriately adjusted in largeness and length in consideration of the size of the stage 1. The radius of the first tubular part 7 may be uniform or may increase as the position shifts from an upstream side to a downstream side. The tubular shape of the first tubular part 7, in cross section, may be circular, elliptic, or rectangular (quadrangular, pentagonal, hexagonal, or octagonal). The first fluid may be a fluid for raising a temperature of the mount surface or may be a fluid for lowering a temperature. It is acceptable that fluids different in purpose of use flow in a single tube.

### First Tube Support Part 9

The first tube support part 9 is an element for supporting the first tubular part 7.

### First Groove Part 11

The first groove part 11 is provided in the stage body 5 and serves as an element for accommodating the first tubular part 7. The first groove part 11 may be provided on the mount surface side of the stage body 5, or may be provided on a back surface (a surface opposite to the mount surface) side. The groove part 11 is a portion lowered in height than its surroundings.

### Paired Notches 13a and 13b

The paired notches 13a and 13b are recessed portions provided at positions facing each other across the first groove part 11. The paired notches 13a and 13b can also be referred to as insertion holes that face each other across the first tubular part 7 and are provided on both sides of the first tubular part 7. The connection part 15 of the first tube support part 9 is insertable into these recessed portions, as described below. As a result, the first tube support part 9 can be fixed via the connection part 15. This causes the first tubular part 7 to be fixed in the first groove part 11. The holes of the paired notches 13a and 13b may be, for example, holes of about 30 mm elongated in the direction in which the tube of the tubular part extends. The holes of the paired notches 13a and 13b may be from 20 mm to 30 mm, may be not less than 21 mm and not greater than 35 mm, in depth. Providing the paired notches 13a and 13b, as a plurality of sets, on the back surface of the stage is preferable. The number of the paired notches 13a and 13b for one stage 1 may be, for example, three, four, or five. If the number of the paired notches 13a and 13b provided in the stage 1 is large, attaching a large number of connection parts 15 will be feasible. Therefore, the first tubular part 7 can be fixed more stably.

The distance from one hole of a set of paired notches 13a and 13b facing each other across a certain groove part 11 to one hole of neighboring paired notches 13a and 13b in the direction in which the tube of the first tubular part 7 extends may be not less than 70 mm and not greater than 100 mm, may be not less than 70 mm and not greater than 110 mm, may be not less than 80 mm and not greater than 100 mm, or may be not less than 80 mm and not greater than 110 mm, for example. The distance between the holes facing each other across the groove part 11, of the set of paired notches 13a and 13b, may be not less than 10 mm and not greater than 15 mm, may be not less than 12 mm and not greater than 15 mm, or may be not less than 15 mm and not greater than 20 mm, for example.

FIG. 4 is a conceptual diagram illustrating the connection part. The connection part 15 can be attached to the paired notches 13a and 13b of the stage 1 so as to cover the tubular part 7 and the groove part 11. The shape of the connection part 15 may be a shape obtainable by processing the shape of a quadrangular prism, for example, in such a manner that one bottom surface is recessed at a central portion thereof. In addition, the central portion is lower in height than peripheral bottom surfaces, and there are walls formed at both ends of this recessed portion. These walls may be protrusions. The height of this protrusion (wall) depends on the depth of the hole of the paired notches 13a and 13b, and may be not less than 10 mm and not greater than 13 mm or may be not less than 13 mm and not greater than 16 mm, for example.

The above-described walls are not required to have a surface facing a central region of the bottom surface and being perpendicular to the bottom surface. The above-described portion of the wall may extend from the central region of the bottom surface of the quadrangular prism in a direction of opening toward the opposite side of the bottom surface. For example, the angle between one of the above protrusions (walls) and an opposing protrusion (wall) may be not less than 30 degrees and not greater than 40 degrees, may be not less than 40 degrees and not greater than 50 degrees, or may be not less than 50 degrees and not greater than 60 degrees.

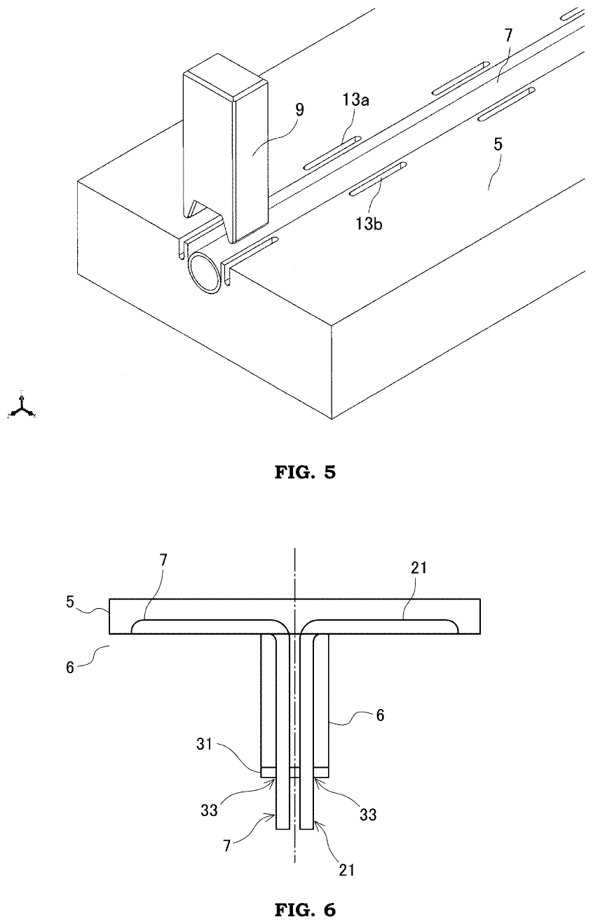

FIG. 5 is a reference diagram illustrating the stage during manufacturing.

A preferable example of the stage includes a heat conductive medium existing in a clearance between the first tubular part 7 and the first groove part 11. Silver, grease, metal fiber, or gas is a preferable example of the heat conductive medium.

FIG. 6 is a conceptual diagram illustrating an exemplary use of the heat conductive medium. Microscopically, there is a minute clearance between the first tubular part 7 and the first groove part 11. Therefore, using the heat conductive medium is effective. Conceivable examples of the heat conductive medium include solids such as carbon fiber, grease-like materials, liquids such as silver, and gases such as hydrogen and helium. In order to prevent the run-off, it is feasible to provide sealing in the case of using the grease-like materials, liquids, and gases.

When the heat conductive medium is a fluid such as a grease-like material, a liquid, or a gas, it is desirable to fill the clearance with the heat conductive medium and prevent the leakage by tight closure. In a simplified example, a sealing plate 31 is attached to an end of the table support 6, the first tubular part 7 and the second tubular part 21 are completely sealed by a sealing part 33. Sealing the heat conductive medium realizes isolation from the atmosphere and prevention of the run-off. When the heat conductive medium is gaseous, filling the clearance with the gas of pressurized state can sharply increase the heat conduction efficiency.

In a preferable example of the stage, the first fluid is a fluid for raising a temperature of the mount surface. The stage further includes the second tubular part 21 causing the second fluid to flow for lowering a temperature of the mount surface, the second groove part 23 for accommodating the second tubular part 21, and the second tube support part 25 for supporting the second tubular part 23. In this case, the first tubular part functions as a heating part. Further, the second tubular part functions as a cooling part.

A second aspect of the present invention relates to a vacuum device including any one of the above-described stages as a susceptor. This vacuum device is, for example, a vacuum device used for manufacturing a semiconductor integrated circuit, a flat display panel, or a solar cell panel. The vacuum device usually includes a chamber and a vacuum pump that evacuates the chamber. Further, the vacuum device may include an introduction part for introducing various samples into the chamber. Further, the vacuum device may appropriately include sensors and measurement devices for performing various measurements. A process chamber for manufacturing objects is an exemplary chamber. Examples of the flat display panel include organic EL displays, plasma displays, and liquid crystal displays.

A third aspect of the present invention relates to a method for manufacturing a semiconductor integrated circuit, a flat display panel, or a solar cell panel, which uses the above-described vacuum device. Methods for manufacturing semiconductor integrated circuits are conventionally known as described in Japanese Patent No. 3956697, Japanese Patent No. 3519589, and Japanese Patent No. 3064993, for example. Methods for manufacturing flat display panels are conventionally known as described in Japanese Patent No. 5173757, Japanese Patent No. 5169757, and Japanese Patent No. 4604752, for example. Methods for manufacturing solar cell panels are conventionally known as described in Japanese Patent No. 6555964, Japanese Patent No. 6498053, and Japanese Patent No. 5386044, for example.

The stage can be manufactured, for example, in the following manner. The manufacturing includes machining a groove (a flow channel) on an aluminium plate having a thickness of 30 to 100 mm, which is a rectangular (for example, square) plate with one side length of 1500 to 4000 mm. Further, the manufacturing includes appropriately forming paired notches on both sides of the groove. The material of the stage body is not limited to aluminium and may be any other metal. The manufacturing further includes inserting a stainless-steel pipe having an outer diameter of φ5 to φ20 into the groove (flow channel) thus obtained. Following the insertion of the pipe into the groove, the tube support part is inserted into the paired notches. The tube support part may be optionally welded. The stage can be manufactured in this manner.

### Practical Example

Manufacturing of the susceptor was implemented in the following manner. A flow channel was processed in an aluminium plate of material A6061. Temperature control was performed with a heater or a flowing heat conductive medium. The stage (susceptor) is normally used in a vacuum device. However, for the purpose of temperature change measurement, the temperature change was measured in the atmosphere in this example.

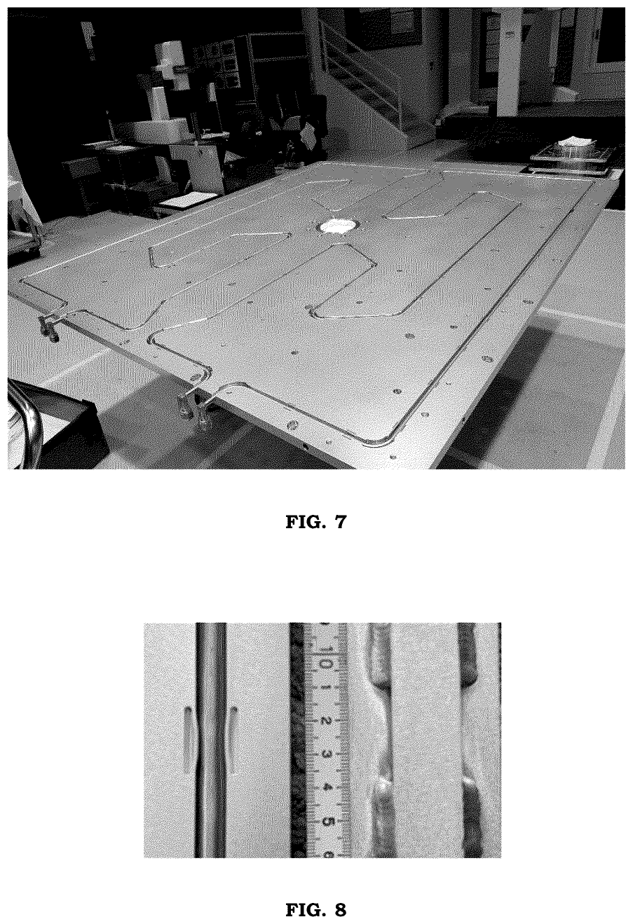

FIG. 7 is a photograph in lieu of a drawing showing a back surface of a stage on which grooves and notched parts are formed. FIG. 8 is a photograph in lieu of a drawing showing how the tube support part is welded.

1. A stage (1) installed in a chamber for heating and cooling an object, the stage (1) comprising:
a stage body (5) with a mount surface for mounting the object;
a first tubular part (7) that causes a first fluid to flow for temperature adjustment of the mount surface; and
a first tube support part (9) for supporting the first tubular part (7), wherein
the stage body (5) includes:
a first groove part (11) for accommodating the first tubular part (7); and
paired notches (13a and 13b) facing each other across the first groove part (11),
the first tube support part (9) includes
a connection part (15) for connecting the paired notches (13a and 13b),
the first fluid is a fluid for raising a temperature of the mount surface,
the stage body (5) further includes:
a second tubular part (21) that causes a second fluid to flow for lowering a temperature of the mount surface;
a second groove part (23) for accommodating the second tubular part (21); and
a second tube support part for supporting the second tubular part (21), the second tube support part being separate from the first tube support part (9),
the stage body (5) includes
second paired notches facing each other across the second groove part (23), and
the second tube support part includes
a second connection part (25) for connecting the second paired notches.

2. The stage according to claim 1, wherein a heat conductive medium exists in a clearance between the first tubular part (7) and the first groove part (11).

3. The stage according to claim 2, wherein the heat conductive medium is silver, grease, metal fiber, or gas.

4. (canceled)

5. A vacuum device comprising the stage according to claim 1 as a susceptor.

6. The vacuum device according to claim 5, which is used for manufacturing a semiconductor integrated circuit, a flat display panel, or a solar cell panel.

7. A method for manufacturing a semiconductor integrated circuit, a flat display panel, or a solar cell panel using the vacuum device according to claim 5.

8. The stage according to claim 1, wherein
the connection part (15) includes:
a quadrangular prism-shaped body part;
a flat surface part centrally located on an upper surface of the body part; and
two walls existing on both sides of the flat surface part,
the two walls correspond to the paired notches (13a and 13b),
the second connection part (25) includes:
a second body part having a quadrangular prism shape;
a second flat surface part centrally located on an upper surface of the second body part; and
two second walls existing on both sides of the second flat surface part, and
the two second walls correspond to the second paired notches.

9. A vacuum device comprising the stage according to claim 2 as a susceptor.

10. The vacuum device according to claim 9, which is used for manufacturing a semiconductor integrated circuit, a flat display panel, or a solar cell panel.

11. A method for manufacturing a semiconductor integrated circuit, a flat display panel, or a solar cell panel using the vacuum device according to claim 9.

12. A vacuum device comprising the stage according to claim 3 as a susceptor.

13. The vacuum device according to claim 12, which is used for manufacturing a semiconductor integrated circuit, a flat display panel, or a solar cell panel.

14. A method for manufacturing a semiconductor integrated circuit, a flat display panel, or a solar cell panel using the vacuum device according to claim 12.
